(19) United States
(12) Patent Application Publication
(10) Pub. No.: US 2012/0313484 A1
(43) Pub. Date: Dec. 13, 2012

(54) ULTRASONIC SENSOR

(75) Inventors: Boum Seock Kim, Gyeonggi-do (KR); Sung Kwon Wi, Seoul (KR); Eun Tae Park, Gyeonggi-do (KR)

(73) Assignee: SAMSUNG ELECTRO-MECHANICS CO., LTD., Suwon (KR)

(21) Appl. No.: 13/464,498

(22) Filed: May 4, 2012

(30) Foreign Application Priority Data
Jun. 9, 2011 (KR) 10-2011-0055708

(51) Int. Cl. H01L 41/04

(52) U.S. Cl. 310/315

(57) ABSTRACT

Disclosed herein is an ultrasonic sensor, including: a conductive case having at least one groove disposed on a bottom surface thereof; a piezoelectric element fixed to the bottom surface of the case through a non-conductive adhesive; a conductive adhesive injected into the groove to electrically connect the case to the piezoelectric element; a temperature compensation capacitor disposed on an upper portion of the piezoelectric element; a first lead wire led-in from the outside of the case and being electrically connected to one surface of the temperature compensation capacitor and the piezoelectric element; and a second lead wire led-in from the outside of the case and being electrically connected to the other surface of the temperature compensation capacitor and the case.

### CROSS REFERENCE(S) TO RELATED APPLICATIONS

This application claims the benefit under 35 U.S.C. Section 119 of Korean Patent Application Serial No. 10-2011-0055708, entitled “Ultrasonic Sensor” filed on Jun. 9, 2011, which is hereby incorporated by reference in its entirety into this application.

### BACKGROUND OF THE INVENTION

1. Technical Field

The present invention relates to a sensor, and more particularly, to an ultrasonic sensor used to measure a distance to objects to be measured by generating an ultrasonic wave using a piezoelectric element and sensing the ultrasonic wave reflected from the objects to be measured, the reflected wave.

2. Description of the Related Art

As an ultrasonic sensor, two types such as a piezoelectricity type and a magentostriction type have been generally used. The piezoelectricity type means a type using a phenomenon of inducing voltage when pressure is applied to objects such as crystal, PZT (piezoelectric material), piezoelectric polymer, or the like, and to the contrary, inducing vibrations when voltage is applied thereto. On the other hand, the magnetostriction type means a type using a Joule effect (a phenomenon generating vibrations when applying magnetic field) and a Villari effect (a phenomenon generating magnetic field when applying stress) that are shown on an alloy of iron, nickel, and cobalt, or the like.

An ultrasonic element may be referred to as an ultrasonic sensor and an ultrasonic generator. The piezoelectricity type senses the ultrasonic wave using voltage generated when ultrasonic vibrations are applied to the piezoelectric element and generates the ultrasonic wave by vibrations generated when voltage is applied to the piezoelectric element. The magnetostriction type generates the ultrasonic wave by the Joule effect and senses the ultrasonic wave by the Villari effect.

Currently, the ultrasonic sensor generally used is operated by the piezoelectricity type using the piezoelectric element and has a structure in which the piezoelectric element is seated in a case and the ultrasonic wave generated from the piezoelectric element is discharged to the outside through the case. Since a case of the ultrasonic sensor having the above structure serves as an electrode of the piezoelectric element, the case uses a conductive material and the piezoelectric element and the case are electrically connected to each other by a conductive adhesive.

However, the conductive adhesive includes filler for conduction and is thicker about two times than a general non-conductive adhesive. Therefore, the ultrasonic wave generated from the piezoelectric element is partially absorbed into the conductive adhesive before being transferred to the case, such that the intensity of the ultrasonic wave finally radiated is weaker than the intensity of the ultrasonic wave first generated. When the ultrasonic intensity is weak, there is a problem in that an arrival distance of the ultrasonic wave becomes short and thus, the sensing distance of the ultrasonic sensor becomes short accordingly.

### SUMMARY OF THE INVENTION

An object of the present invention is to provide an ultrasonic sensor capable of remarkably improving intensity of ultrasonic wave generated from a piezoelectric element and transferred to the outside through a case by making a thickness of an adhesive used when the piezoelectric element is attached to the case thinner.

According to an exemplary embodiment of the present invention, there is provided an ultrasonic sensor, including: a conductive case having at least one groove disposed on a bottom surface thereof; a piezoelectric element fixed to the bottom surface of the case through a non-conductive adhesive; a conductive adhesive injected into the groove to electrically connect the case to the piezoelectric element; a temperature compensation capacitor disposed on an upper portion of the piezoelectric element; a first lead wire lead-in from the outside of the case and being electrically connected to one surface of the temperature compensation capacitor and the piezoelectric element; and a second lead wire lead-in from the outside of the case and being electrically connected to the other surface of the temperature compensation capacitor and the case.

The ultrasonic sensor may further include a seating part protrudedly formed on the bottom surface of the case and fixed with the piezoelectric element.

An upper surface side portion of the seating part may be provided with at least one auxiliary groove accommodating the non-conductive adhesive.

The ultrasonic sensor may further include a sound absorbing material disposed on the upper portion of the piezoelectric element.

The ultrasonic sensor may further include a molding part filled in the case

### BRIEF DESCRIPTION OF THE DRAWINGS

FIG. 1 is a perspective view of an ultrasonic sensor according to an exemplary embodiment of the present invention.

FIG. 2 is a cross-sectional view taken along line A-A′ shown in FIG. 1.

FIG. 3 is a partially enlarged view of portion C shown in FIG. 2.

FIG. 4 is a perspective view showing a seating part shown in FIG. 3.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

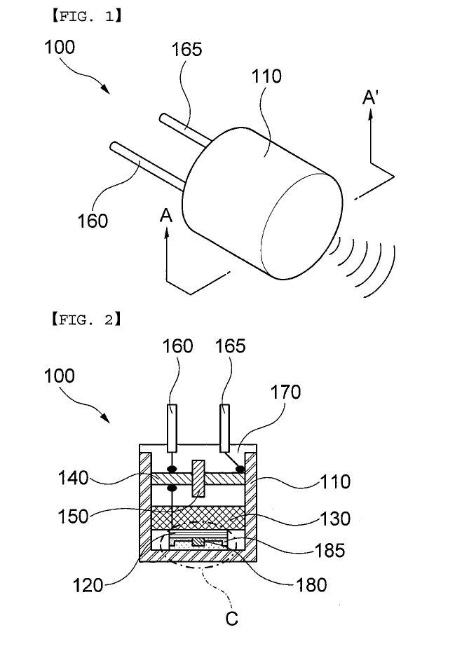

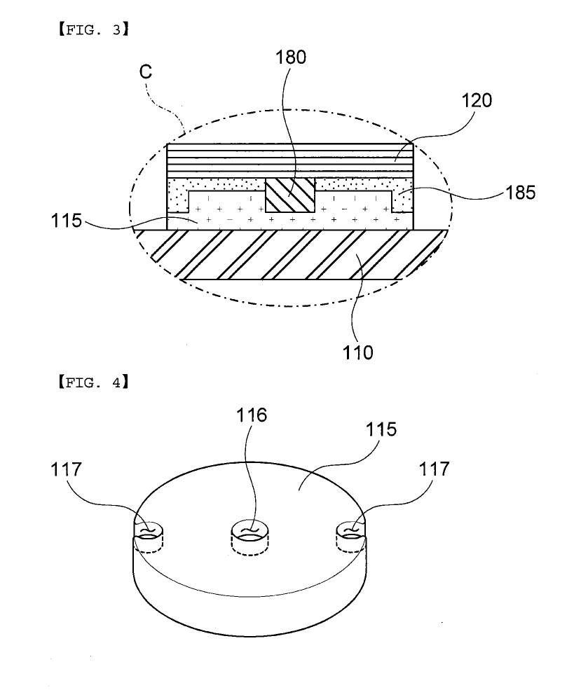

FIG. 1 is a perspective view of an ultrasonic sensor according to an exemplary embodiment of the present invention, FIG. 2 is a cross-sectional view taken along line A-A′ shown in FIG. 1, FIG. 3 is a partially enlarged view of portion C shown in FIG. 2, and FIG. 4 is a perspective view showing a seating part shown in FIG. 3. Referring to FIGS. 1 to 4, an ultrasonic sensor 100 according to an exemplary embodiment of the present invention includes a case 110, a piezoelectric element 120, a conductive adhesive 180, a temperature compensation capacitor 150, a first lead wire 160, and a second lead wire 165.

The case 110 made of a conductive material has a space in which parts may be accommodated and a bottom surface thereof is provided with at least one groove 116. In addition, the bottom surface of the case 110 is provided with the piezoelectric element 120 that generates an ultrasonic wave.

The piezoelectric element 120 is a part that is displaced when current is applied thereto. Therefore, the piezoelectric element 120 is expanded or contracted according to polarity of current. Therefore, when the polarity of current applied to the piezoelectric element 120 is repeatedly changed, the piezoelectric element 120 generates vibrations by repeating the expansion and contraction. The ultrasonic wave is generated from the piezoelectric element 120 by the above principle.

In addition, the piezoelectric element 120 is bonded to the bottom surface of the case 110 through a non-conductive adhesive 185 and the conductive adhesive 180 for electrically connecting the case 110 to the piezoelectric element 120 is injected into the groove 116 formed in the case 110.

Generally, the piezoelectric element is attached to the case through the conductive adhesive for electrically connecting to the case, wherein the conductive adhesive is applied thicker than the non-conductive adhesive. Since the conductive adhesive includes Ag filler for conduction, the conductive adhesive may not be applied at a thickness equal to or smaller than the size of the Ag filler. Describing the case of epoxy as an example, an applying thickness of general conductive epoxy is 7 to 10 μm and an applying thickness of non-conductive epoxy is 2 to 4 μm, which has a difference in thickness about two times therebetween.

However, in the exemplary embodiment of the present invention, the piezoelectric element 120 is bonded to the case 110 by the non-conductive adhesive 185, the piezoelectric element 120 has a thin adhesive layer about half the case in which the piezoelectric element 120 is bonded to the case 110 by the conductive adhesive. Therefore, the intensity of the ultrasonic wave generated from the piezoelectric element 120 and transferred to the outside through the case 110 may be improved.

Generally, the vibration force of the piezoelectric element 120 is in proportion to a material constant of the case 110 and an effective piezoelectric constant of the piezoelectric element 120 and is in inverse proportion to the thickness of the adhesive disposed between the case 110 and the piezoelectric element 120. Therefore, the ultrasonic sensor 100 according to the exemplary embodiment of the present invention may obtain an effect of increasing the intensity of the ultrasonic wave 20 to 30% or more than the ultrasonic sensor according to the related art and thus, the sensing distance may be improved.

In this case, the conductive adhesive 180 may be the conductive epoxy and the non-conductive adhesive 185 may be the non-conductive epoxy.

Meanwhile, the piezoelectric element 120 has property in which the capacitance thereof is changed according to temperature. The reverberation vibration of the piezoelectric element 120 is increased at low temperature the change in the capacitance value, such that the piezoelectric element 120 is mal-functional and the sensitivity of the piezoelectric element is degraded at high temperature, such that the sensing distance thereof is reduced.

In order to prevent the above phenomenon, the change value in capacitance of the piezoelectric element 120 is compensated by the temperature compensation capacitor 150. The temperature compensation capacitor 150 is disposed on the upper portion of the piezoelectric element 120 and is fixed through the substrate 140.

The first lead wire 160 is lead-in from the outside of the case 110 and is electrically connected to one surface of the temperature compensation capacitor 150 and the piezoelectric element 120. Further, the second lead wire 165 is lead-in from the outside of the case 110 and is electrically connected to the other surface of the temperature compensation capacitor 150 and the case 110.

Meanwhile, the ultrasonic sensor 100 according to the exemplary embodiment of the present invention may further include a seating part 115 protrudedly formed on the bottom surface of the case 110. The seating part 115 is bonded to the piezoelectric element 120 by the non-conductive adhesive 185 and is provided with the groove 116 into which the conductive adhesive 180 is injected. It can prevent the rigidity of the case 110 from being degraded due to the groove 116 formed on the bottom surface of the case 110 by protrudedly forming the seating part 115 on the bottom surface of the case 110.

Further, the seating part 115 may be provided with at least one auxiliary groove 117. The auxiliary groove 117 is formed on the upper side of the seating part 115 and serves to allow the non-conductive adhesive 185 to flow down along the auxiliary groove 117

When the piezoelectric element 120 is bonded to the upper portion of the seating part 115, the non-conductive adhesive 185 applied to the seating part 115 overflows to the outside of the seating part 115 while being compressed by the piezoelectric element 120. In this case, the extra non-conductive adhesive 185 overflowing has the high viscosity and thus, may go up the side of the piezoelectric element 120.

In order to prevent the above problems, the auxiliary groove 117 serves to allow the extra non-conductive adhesive 185 overflowing to the outside of the seating part 115 to fall down the seating part 115 while preventing the extra non-conductive adhesive 185 from going up the side of the piezoelectric element 120.

Further, the ultrasonic sensor 100 according to the exemplary embodiment of the present invention may include a sound absorbing material 130 disposed on the upper portion of the piezoelectric element 120. The sound absorbing material 130 reduces the reverberation shown after the ultrasonic wave is generated from the piezoelectric element 120.

The piezoelectric element 120 serves to generate the ultrasonic wave and sense the ultrasonic wave reflected and returned to the object to be measured, which may easily sense the reflected ultrasonic wave only in the case in which the reverberation shown after the ultrasonic wave is generated is completely removed.

Therefore, when the reverberation of the piezoelectric element 120 is last long, it takes much time to sense the ultrasonic wave and thus, it takes much time for the ultrasonic sensor 100 to sense the distance.

As described above, the sound absorbing material 130 serves to shorten the sensing time of the ultrasonic sensor 100 by reducing the reverberation generated from the piezoelectric element 120.

In addition, the ultrasonic sensor 100 according to the exemplary embodiment of the present invention may further include a molding part 170. The molding part 170, which is manufactured by injecting and hardening a molding solution into the case 110, serves to fix and protect the parts disposed in the case 110.

As set forth above, the ultrasonic sensor according to the exemplary embodiment of the present invention can increase the sensing distance of the ultrasonic sensor by improving the intensity of the ultrasonic wave generated from the piezoelectric element and transferred to the outside through the case.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

1. An ultrasonic sensor, comprising:
a conductive case having at least one groove disposed on a bottom surface thereof;
a piezoelectric element fixed to the bottom surface of the case through a non-conductive adhesive;
a conductive adhesive injected into the groove to electrically connect the case to the piezoelectric element;
a temperature compensation capacitor disposed on an upper portion of the piezoelectric element;
a first lead wire lead-in from the outside of the case and being electrically connected to one surface of the temperature compensation capacitor and the piezoelectric element; and
a second lead wire lead-in from the outside of the case and being electrically connected to the other surface of the temperature compensation capacitor and the case.

2. The ultrasonic sensor according to claim 1, further comprising a seating part protrudedly formed on the bottom surface of the case and fixed with the piezoelectric element.

3. The ultrasonic sensor according to claim 1, wherein an upper surface side portion of the seating part is provided with at least one auxiliary groove accommodating the non-conductive adhesive.

4. The ultrasonic sensor according to claim 1, further comprising a sound absorbing material disposed on the upper portion of the piezoelectric element.

5. The ultrasonic sensor according to claim 1, further comprising a molding part filled in the case.

6. The ultrasonic sensor according to claim 2, further comprising a sound absorbing material disposed on the upper portion of the piezoelectric element.

7. The ultrasonic sensor according to claim 3, further comprising a sound absorbing material disposed on the upper portion of the piezoelectric element.

8. The ultrasonic sensor according to claim 2, further comprising a molding part filled in the case.

9. The ultrasonic sensor according to claim 3, further comprising a molding part filled in the case.
